(19) United States
(12) Patent Application Publication
(10) Pub. No.: US 2016/0203949 A1
(43) Pub. Date: Jul. 14, 2016

(54) CHARGED PARTICLE BEAM DRAWING APPARATUS

(71) Applicant: NuFlare Technology, Inc., Yokohama-shi (JP)

(72) Inventors: Hiroyasu SAITO, Yokohama (JP); Keita IDENO, Yokosuka (JP)

(73) Assignee: NuFlare Technology, Inc., Yokohama-shi (JP)

(21) Appl. No.: 14/987,867

(22) Filed: Jan. 5, 2016

(30) Foreign Application Priority Data
Jan. 9, 2015 (JP) 2015-002799

(51) Int. Cl. H01J 37/304; H01J 37/317

(52) U.S. Cl. CPC H01J 37/3045; H01J 37/3174; H01J 2237/31725; H01J 2237/30472; H01J 2237/202

(57) ABSTRACT

A charged particle beam drawing apparatus has a vacuum container including a bottom plate, the bottom plate including a curved portion curved externally and a plurality of supporting portions disposed on an outer periphery of the curved portion, a stage provided in the vacuum container and having a target object mounted on the stage, a stage actuator supported by the supporting portions in the vacuum container and to move the stage, a two dimensional scale provided on a lower surface of the stage, a detector disposed under the two dimensional scale and detecting a position of the stage by the two dimensional scale, and a support body including a plurality of end portions individually attached to the supporting portions, and to support the detector across the curved portion.

### CROSS REFERENCE TO RELATED APPLICATIONS

This application is based upon and claims the benefit of priority from the prior Japanese Patent Application No. 2015-2799, filed on Jan. 9, 2015, the entire contents of which are incorporated herein by reference.

### FIELD

The present invention relates to a charged particle beam drawing apparatus.

### BACKGROUND

In accordance with recent increase in integration and capacity of large scale integration (LSI) circuits, the widths of circuit lines required for semiconductor devices become increasingly smaller. Lithography technique is used to form a desired circuit pattern on a semiconductor device, and pattern transfer using an original drawing pattern referred to as a mask (reticle) is performed in the lithography technique. To produce a high accuracy mask used in the pattern transfer, a charged particle beam drawing apparatus having excellent resolution is used.

The charged particle beam drawing apparatus is configured to move a stage, on which a target object such as a mask or a blank is supported, in a vacuum container, while deflecting a charged particle beam to a predetermined position on the target object mounted on the stage to draw a pattern on the target object. Such a charged particle beam drawing apparatus detects the position of the stage by a laser interferometer disposed on the side face of the vacuum container, and performs drawing control according to the detected position of the stage.

However, the vacuum container may be slightly deformed due to the influence of the atmospheric pressure (pressure difference) when the pressure decreases in the vacuum container and the vacuum container enters a vacuum state. At this time, the side face of the vacuum container is deformed and the laser interferometer disposed on the side face is tilted. This may deteriorate measurement accuracy of the position of the stage. It is desired to suppress such a deterioration of the measurement accuracy of the position of the stage.

### BRIEF DESCRIPTION OF THE DRAWINGS

FIG. 1 is a schematic diagram illustrating the structure of a charged particle beam drawing apparatus according to an embodiment;

FIG. 2 is a lateral cross-sectional view (a cross-sectional view cut along line A1-A1 of FIG. 1) schematically illustrating the structure of a drawing chamber, a stage moving mechanism, and a stage position measuring portion according to the embodiment;

FIG. 3 is a vertical cross-sectional view (a cross-sectional view cut along line A2-A2 of FIG. 2) schematically illustrating the drawing chamber, the stage moving mechanism, and the stage position measuring portion according to the embodiment;

FIG. 4 is a lateral cross-sectional view schematically illustrating the structure of a support body with the stage moving mechanism being removed from FIG. 2 according to the embodiment; and

FIG. 5 is an external perspective view schematically illustrating the structure of the support body according to the embodiment.

### DETAILED DESCRIPTION

A charged particle beam drawing apparatus according to one embodiment has a vacuum container including a bottom plate, the bottom plate including a curved portion curved externally and a plurality of supporting portions disposed on an outer periphery of the curved portion, a stage provided in the vacuum container and having a target object mounted on the stage, a stage actuator supported by the supporting portions in the vacuum container and to move the stage, a two dimensional scale provided on a lower surface of the stage, a detector disposed under the two dimensional scale and detecting a position of the stage by the two dimensional scale, and a support body including a plurality of end portions individually attached to the supporting portions, and to support the detector across the curved portion.

An embodiment will be described below by referring to the accompanying drawings.

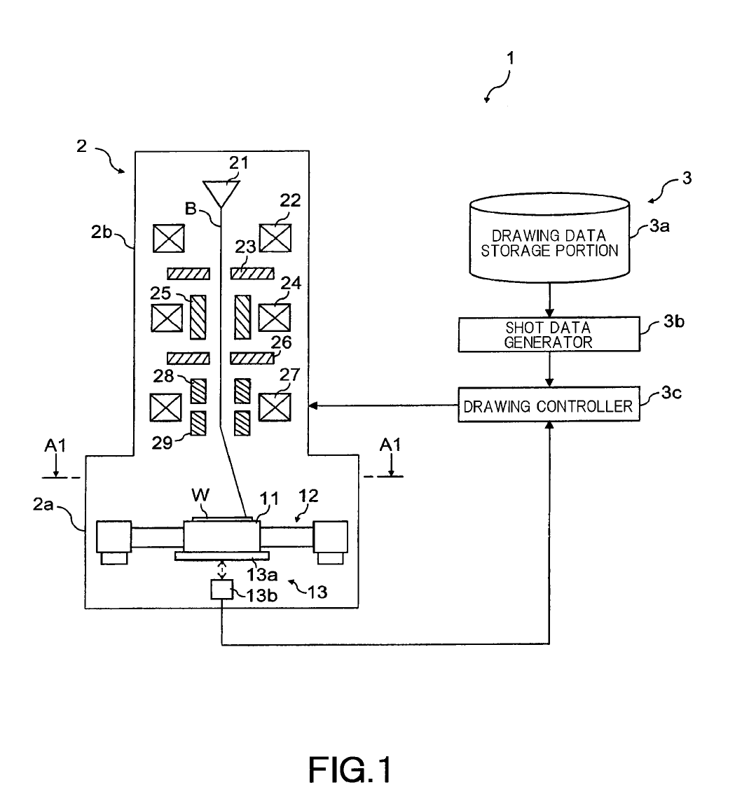

As illustrated in FIG. 1, a charged particle beam drawing apparatus 1 includes a drawing unit 2 that performs drawing with a charged particle beam, and a control unit 3 that controls the drawing unit 2. The charged particle beam drawing apparatus 1 is an example of a variable molding type drawing apparatus using, for example, an electron beam as the charged particle beam. The charged particle beam is not limited to the electron beam, and other charged particle beams, such as an ion beam may be used.

The drawing unit 2 includes a drawing chamber (drawing room) 2a that is provided as a vacuum container for storing a target object W which is subject to drawing. The drawing unit 2 also includes an optical lens barrel 2b coupled with the drawing chamber 2a. The drawing chamber 2a is airtight and functions as a vacuum chamber (decompression chamber). The optical lens barrel 2b is provided on the upper surface of the drawing chamber 2a and forms and deflects the electron beam by an optical system to irradiate the target object W with the electron beam in the drawing chamber 2a. At this time, the interior of both the drawing chamber 2a and the optical lens barrel 2b is decompressed and put in the vacuum state.

The drawing chamber 2a includes a stage 11 that supports the target object W, such as a mask or a blank, a stage moving mechanism (stage actuator) 12 by which the stage 11 is moved, and a stage position measuring unit 13 that measures the position of the stage 11. The stage moving mechanism 12 moves the stage 11 in an X-axis direction and a Y-axis direction (hereinafter simply referred to as X-direction and Y-direction) running perpendicularly to each other in a horizontal plane. The stage position measuring unit 13 (which will be described in detail later) is a measuring unit that detects graduations of a two dimensional scale 13a, which is provided on the lower surface of the stage 11, by an encoder head 13b to measure the position of the stage 11.

The optical lens barrel 2b includes an ejection unit 21, such as an electron gun that ejects an electron beam B, a lighting lens 22 that collects the electron beam B, a first shaping aperture 23 for shaping the beam, a projection lens 24 for projection, a shaping deflector 25 for shaping the beam, a second shaping aperture 26 for shaping the beam, an objective lens 27 that focuses the beam on the target object W, and a sub-deflector 28 and a main deflector 29, both of which are provided to control shot positions of the beam on the target object W. These members 21 to 29 function as the optical system.

In the drawing unit 2, the electron beam B is ejected from the ejection unit 21 to irradiate the first shaping aperture 23 by the lighting lens 22. The first shaping aperture 23 has, for example, a rectangular opening. Therefore, when the electron beam B passes through the first shaping aperture 23, the cross-section of the electron beam B is shaped into a rectangle and the electron beam B is projected to the second shaping aperture 26 by the projection lens 24. The projecting position can be deflected by the shaping deflector 25, and changing the projecting position allows control of the shape and size of the electron beam B. After that, the electron beam B having passed through the second shaping aperture 26 is focused on and ejected to the target object W on the stage 11 by the objective lens 27. At this time, the shot position of the electron beam B on the target object W on the stage 11 can be changed by the sub-deflector 28 and the main deflector 29.

The control unit 3 includes a drawing data storage 3a that stores drawing data, a shot data generator 3b that generates shot data by processing the drawing data, and a drawing controller 3c that controls the drawing unit 2. The control unit 3 may be implemented by hardware, such as an electric circuit, by software, such as a program that executes various functions, or by a combination thereof.

The drawing data storage 3a is a storage that stores drawing data for drawing a pattern on the target object W. The drawing data is design data (layout data) converted in accordance with the format for the charged particle beam drawing apparatus 1, and externally input to and stored in the drawing data storage 3a. As the drawing data storage 3a, a magnetic disc apparatus, a semiconductor disc apparatus (flash memory) or the like may be used. The drawing data is compressed, for example, in accordance with a layered structure of data or arrayed display of patterns. Such drawing data is used as data for defining the drawing pattern and the like of a chip region.

The shot data generator 3b divides a drawing pattern defined by the drawing data into stripe-shaped (narrow rectangular shaped) stripe regions (in which the longitudinal direction thereof is in the X-direction and the short-width direction thereof is in the Y-direction). The shot data generator 3b further divides each of the stripe regions Ra into a large number of matrix-shaped sub-regions. In addition, the shot data generator 3b determines a shape, size, and a position of a figure in each of the sub-regions to generate shot data. A length in the short-length direction (Y-direction) of the stripe region is set such that the electron beam B can be deflected by main deflection.

During drawing of the drawing pattern mentioned above, the drawing controller 3c positions the electron beam B in each of the sub-regions by the main deflector 29, while moving the stage 11 in the longitudinal direction (the X-direction) of the stripe region by the stage moving mechanism 12. The drawing controller 3c then shoots the electron beam B to a predetermined position in each of the sub-regions by a sub-deflector 28 to draw the figure. When the drawing is finished in one stripe region, the stage 11 is moved stepwise in the Y-direction before the drawing of the next frame region is started. This step is repeated until the entire drawing region of the target object W is drawn with the electron beam B (an example of a drawing operation). Since the stage 11 is continuously moved in one direction during the drawing, the origin of the drawing in each of the sub-regions is tracked by the main deflector 29 such that the origin of the drawing can follow the movement of the stage 11.

In such a drawing operation with the electron beam B, the position information of the stage 11 measured by the stage position measuring unit 13 is used not only for the control (feedback control) regarding the movement of the stage 11, but also for the control of the sub-deflector 28 and the main deflector 29, i.e., the control of the irradiation position (control of the drawing). Therefore, the measurement accuracy of the stage position measuring unit 13 largely affects the drawing accuracy.

Next, the stage moving mechanism 12 and the stage position measuring unit 13 are described in detail.

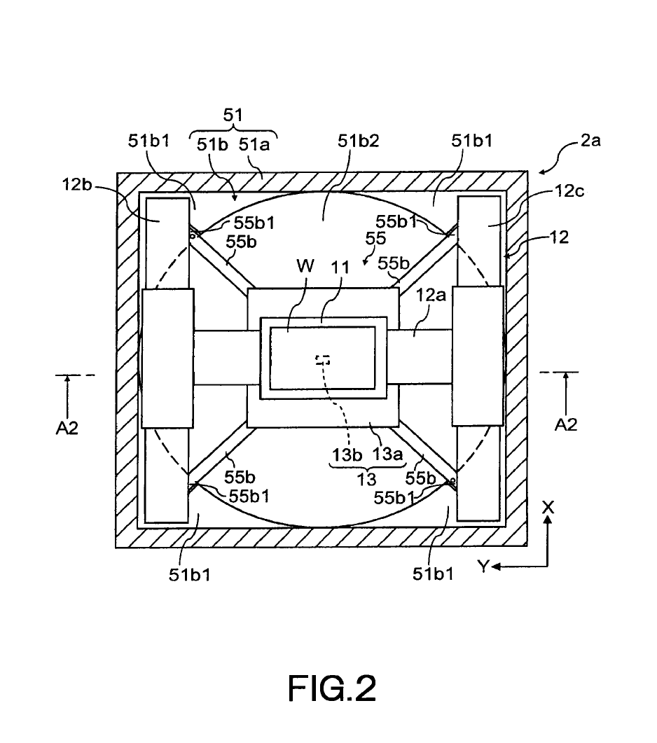

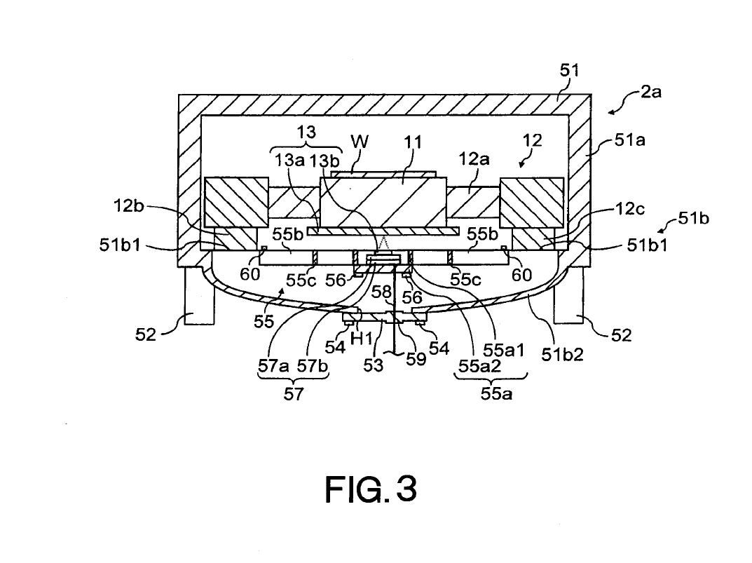

As illustrated in FIGS. 2 and 3, the stage moving mechanism 12 includes a Y-direction moving mechanism 12a that moves the stage 11 on which the target object W is mounted in the Y-direction, and a pair of X-direction moving mechanisms 12b and 12c that moves the Y-direction moving mechanism 12a in the X-direction.

The Y-direction moving mechanism 12a supports and guides the stage 11 to move it in the Y-direction. The pair of X-direction moving mechanisms 12b and 12c supports and guides the Y-direction moving mechanism 12a to move it with the stage 11 in the X-direction. The moving mechanisms 12a to 12c may be implemented by various types of moving mechanisms, such as an air-stage system moving mechanism, a linear motor type moving mechanism, a feed screw type moving mechanism, or the like.

The stage position measuring unit 13 includes the two dimensional scale 13a provided on the lower surface of the stage 11, and the encoder head 13b provided as a detector for detecting graduations of the two dimensional scale 13a. The stage position measuring unit 13 detects graduations of the scale of the two dimensional scale 13a by the encoder head 13b to measure the position of the stage 11.

The two dimensional scale 13a has latticed graduations (e.g., grating) that extend in the X- and Y-directions. The graduations of the scale are formed detectable by the encoder head 13b and equally arranged in the X- and Y-directions. The two dimensional scale 13a may be implemented by various types of two dimensional scales. The two dimensional scale 13a has the graduations at least in two directions (e.g., the X- and Y-directions).

The encoder head 13b is a reflection type laser sensor that ejects laser light to the two dimensional scale 13a and receives reflected laser light from the two dimensional scale 13a. The encoder head 13b measures length by counting a graduation of the two dimensional scale 13a. That is, the encoder head 13b detects the position of the stage 11 according to the two dimensional scale 13a. The encoder head 13b may be implemented by various encoder heads other than the reflection type laser sensor so long as the encoder head is provided corresponding to the two dimensional scale 13a and capable of detecting graduations of the scale.

One encoder head 13b has been provided in the embodiment, but the number of the encoder heads 13b is not limited to one and, for example, two, three, or more than three encoder heads 13b may be provided. If, for example, more than one encoder head 13b is provided, it is possible to detect the direction of rotation (yawing), in addition to the X- and Y-directions.

Next, the drawing chamber 2a is described in detail.

As illustrated in FIGS. 2 and 3, the drawing chamber 2a includes a housing 51, which is formed as a body of the drawing chamber 2a, and a plurality of legs 52 (see FIG. 3) that support the housing 51. The legs 52 are provided individually at four corners of the housing 51. The optical lens barrel 2b (see FIG. 1) is fixed on the upper surface of the housing 51 via a sealing member (not illustrated), such as an O ring, approximately at the center of the optical lens barrel 2b. The inside of the optical lens barrel 2b communicates with the inside of the housing 51.

The housing 51 includes a side wall (outer peripheral wall) 51a, which is formed as a wall of the outer periphery, and a bottom plate 51b on which the stage moving mechanism 12 is disposed. The bottom plate 51b includes a plurality of supporting portions 51b1 that support the stage moving mechanism 12 with the stage 11, and a curved portion 51b2 having a protruding shape that is curved and protruding externally from the drawing chamber 2a. The supporting portions 51b1 and the curved portion 51b2 are formed integrally with the side wall 51a.

The supporting portions 51b1 are formed individually at the four corners of the housing 51, that is, the four corners of the bottom plate 51b (around the curved portion 51b2). The supporting portions 51b1 continue to the side wall 51a and become part of the bottom plate 51b. Upper surfaces of the supporting portions 51b1 are provided as installing surfaces (stage mounting surfaces) on which end portions of a pair of X-direction moving mechanisms 12b and 12c are individually disposed. The X-direction moving mechanisms 12b and 12c are supported by the supporting portions 51b1.

The curved portion 51b2 is arranged in the center of the bottom plate 51b and coupled with the supporting portions 51b1. Thus, the curved portion 51b2 and the supporting portions 51b1 form the bottom plate 51b. The curved portion 51b2 is formed in a cup shape (or a hollow semispherical shape) that curves externally from the housing 51, that is, in a direction opposite to the stage 11 disposed in the housing 51. The curved portion 51b2 has a curved surface that continues to the individual installing surfaces of the supporting portions 51b1.

The curved portion 51b2 may have, for example, a uniform thickness, and the thickness may be smaller than the thicknesses of the supporting portions 51b1. A degree of the curve (curvature) of the curved portion 51b2 is determined, according to the thickness of the curved portion 51b2 and the thickness of the side wall 51a, so as not to deform the supporting portions 51b1 when the drawing chamber 2a is in the vacuum state. The supporting portions 51b1 have the same and uniform thicknesses, but the thicknesses are not limited thereto. In addition, the curved portion 51b2 also has a uniform thickness, but the thickness is not limited thereto.

The curved portion 51b2 has an opening H1 (see FIG. 3) formed as a through hole located below the encoder head 13b. The opening H1 is closed by a lid 53. The opening H1 may be formed, for example, in a circular shape or a square shape with the center of the opening H1 located at the center of the curved portion 51b2. The lid 53 is formed in a plate shape and provided on the lower surface of the drawing chamber 2a (the lower surface of the curved portion 51b2) via a sealing member (not illustrated), such as an O ring. The lid 53 is then fixed with a plurality of fixing members 54, such as bolts. The lid 53 is formed removably (detachably) in response to attaching and detaching of the fixing members 54 to allow open/close of the opening H1.

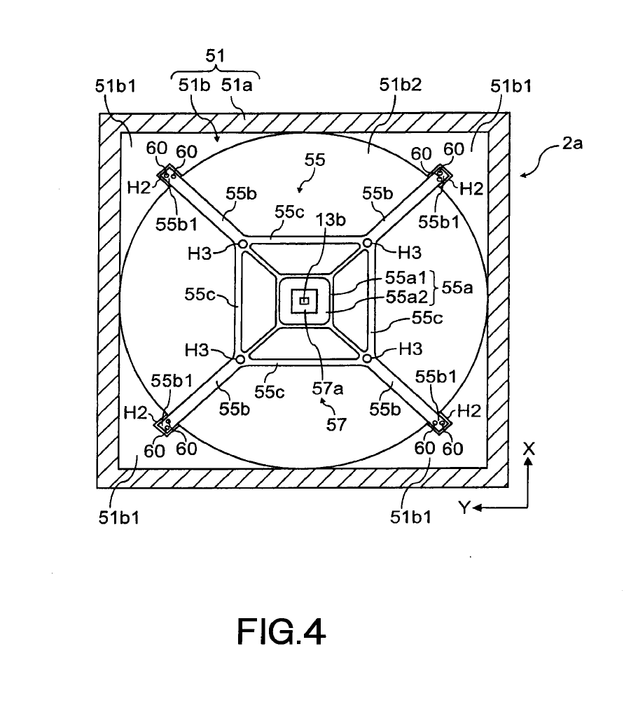

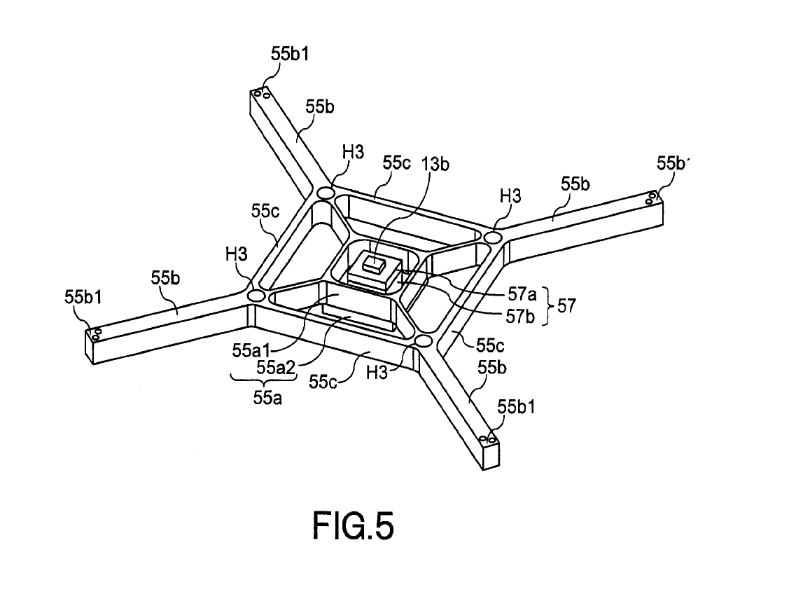

As illustrated in FIGS. 4 and 5, on the supporting portions 51b1, a support body 55 that supports the encoder head 13b is provided (above the curved portion 51b2) to stretch over the curved portion 51b2. The support body 55 includes a storing portion 55a that is a storage chamber in which the encoder head 13b is stored, a plurality of joists 55b formed as extending beams, and a plurality of ribs 55c connecting and reinforcing the joists 55b. Thus the support body 55 functions as a beam-shaped structure body (beam structure body).

The storing portion 55a is formed by a storing frame body 55a1 and a supporting plate 55a2. The storing frame body 55a1 is a rectangular frame body formed approximately in the center of the support body 55. A cross-section of the storing frame body 55a1 perpendicular to the extending direction (a cross-section in the short-length direction) of the storing frame body 55a1 is in a longitudinal rectangular shape. The supporting plate 55a2 is a plate member that supports the encoder head 13b and is fixed on the lower surface of the storing frame body 55a1 with the fixing members 56 (see FIG. 3), such that the encoder head 13b is disposed in the storing frame body 55a1. The supporting plate 55a2 can be attached and removed from the lower side, i.e., the side of the curved portion 51b2, by attaching and detaching of the fixing members 56. Specifically, the lid 53 is removably provided under the supporting plate 55a2, and the supporting plate 55a2 can easily be removed by first removing the lid 53.

The encoder head 13b is disposed on the supporting plate 55a2 via a position adjusting unit 57. The position adjusting unit 57 is provided on the supporting plate 55a2 to adjust the position of the encoder head 13b relative to the two dimensional scale 13a which is provided under the stage 11. The position adjusting unit 57 includes an angle adjusting mechanism (tilting mechanism) 57a that changes an angle (incident angle of the laser light) of the encoder head 13b relative to the two dimensional scale 13a, and a vertical moving mechanism 57b that works with the angle adjusting mechanism 57a to move the encoder head 13b vertically. The position adjusting unit 57 and the encoder head 13b are connected to the drawing controller (see FIG. 1) by a cable 58 (see FIG. 3). The cable 58 is taken out of the drawing chamber 2a via a feedthrough 59 (see FIG. 3) attached to the lid 53.

The position adjusting unit 57 performs position adjustment (e.g., adjustment of an angle, clearance, and so on) in response to the input operation by a user when an input unit (not illustrated), such as buttons and keys, is operated during fine adjustment (initial fine adjustment) or the like at the time of disposing the encoder head 13b. However, the position adjustment of the position adjusting unit 57 is not limited to this. For example, the position adjusting unit 57 may automatically adjust the position to return to the original position in a case where the position of the encoder head 13b is shifted relative to the two dimensional scale 13a from the initial value for some reason after the fine adjustment. Alternatively, the automatic position adjustment of the position adjusting unit 57 may be performed according to other factors. More specifically, the position adjusting unit 57 is configured by using, for example, a linear motor stage, a piezo stage or the like capable of moving in a two-dimensional direction.

The joists 55b are square bars. Each square bar extends horizontally from the four corners of the storing frame body 55a1 and becomes thicker in the middle of the square bar (i.e., the length in the vertical direction is fixed and the width in the horizontal direction is increased). The cross-section (the cross-section in the short-length direction) of each of the joists 55b is in a longitudinally rectangular shape. End portions 55b1 of the joists 55b are attached to each of the supporting portions 51b1. Specifically, a recessed portion H2 (see FIG. 4) is formed on each of the installing surfaces of the supporting portions 51b1, and the end portion 55b1 of each of the joists 55b is put into the recessed portion H2 and fixed by the fixing members 60, such as the bolts. Thus, the support body 55 is formed removably by attaching and detaching of the fixing members 60. The depth of the recessed portion H2 is set such that the end portion 55b1 of each of the beam member 55b does not project from the installing surface of the supporting portion 51b1.

The ribs 55c are square bars that connect the adjacent joists 55b among the joists 55b, and the cross-section (the cross-section in the short-length direction) of each of the rib 55c perpendicular to the extending direction is in a longitudinally rectangular shape. Each of the ribs 55c connects the inner most side of the thick portion of the beam member 55b to the inner most side of the thick portion of the adjacent joists 55b respectively, to thereby connect all ribs 55c to form the frame body. A through hole H3 is formed in the thick portion of the beam member 55b to reduce the weight.

Next, the vacuum state (decompressed state) of the charged particle beam drawing apparatus 1 is described.

Before starting the drawing, the drawing chamber 2a and the optical lens barrel 2b are made to be in the vacuum state by decompressing the interior of the chambers to a predetermined vacuum level. After that, the drawing with the electron beam B is executed. Since both the interior of the drawing chamber 2a and the interior the optical lens barrel 2b are in the vacuum state, the side wall 51a and the curved portion 51b2 of the drawing chamber 2a are deformed by atmospheric pressure (pressure difference). For example, the side wall 51a may be finely deformed (e.g., about several tens to several hundreds of μm) so as to be bent externally or internally from and to the housing 51. The curved portion 51b2 is also deformed, for example, internally to the housing 51. When the vacuum state is cancelled, the side wall 51a and the curved portion 51b2 are returned to the original state (original shape).

At the time of the deformation, a force applied to the supporting portions 51b1 due to the deformation of the side wall 51a is offset by the force applied to the supporting portions 51b1 due to the deformation of the curved portion 51b2. Thus, the deformation of the supporting portions 51b1 can be suppressed. Specifically, as the curved portion 51b2 is deformed, the force to spread out the curved portion 51b2 toward the outer periphery of the housing 51 acts on the supporting portions 51b1. This prevents tilting of the installing surfaces of the supporting portions 51b1 caused by the deformation of the side wall 51a, and maintains the installing surfaces in the horizontal state. Accordingly, it is possible to suppress the deformation of the supporting portions 51b1.

By using the bottom plate 51b having the curved structure, the deformation of the supporting portions 51b1 can be suppressed, and the tilting of the installing surfaces, which are the upper surfaces of the supporting portions 51b1, can be prevented. The stage moving mechanism 12 and the support body 55 disposed on the supporting portions 51b1 are not tilted, and the positional relationship between the two dimensional scale 13a and the encoder head 13b does not change due to the deformation of the drawing chamber 2a caused by the atmospheric pressure. Even when the drawing chamber 2a is deformed due to the atmospheric pressure, the supporting portions 51b1, which supports the stage moving mechanism 12 and the support body 55, are not deformed. It is, therefore, possible to suppress the tilting of the two dimensional scale 13a and the encoder head 13b caused by the deformation of the drawing chamber 2a due to the atmospheric pressure. This prevents occurrence of measurement errors of the measurement by the stage position measuring unit 13 and suppresses the deterioration of the measurement accuracy of the position of the stage.

The end portions 55b1 of the joists 55b are individually attached to the supporting portions 51b1. Therefore, a contact area between the support body 55 and each of the supporting portions 51b1 is decreased, and the oscillation of the support body 55 due to the oscillation of the housing 51 is suppressed. The occurrence of the measurement error of the measurement by the stage position measuring unit 13 due to the oscillation of the support body 55, that is, the oscillation of the encoder head 13b is suppressed. The deterioration of the measurement accuracy of the position of the stage can thus be minimized. Since the storing frame body 55a1, the ribs 55c, and the like are used in the support body 55, the weight at the center of the support body 55 is reduced such that the vertical oscillation of the support body 55 can be suppressed. Since the joists 55b are made to have longitudinal cross-sections perpendicular to the extending directions, the vertical oscillation of the support body 55 can be further suppressed. The ribs 55c provided in the support body 55 can suppress twisting of the support body 55 (e.g., vertical or horizontal twisting of the joists 55b). A deterioration of the measurement accuracy of the position of the stage can be further suppressed.

If the laser interferometer for measuring the position of the stage is attached to the side wall 51a, the measurement error is several nm/1 hPa in both X- and Y-directions. If, however, the stage position measuring unit 13 described above is used, the measurement error is about 0.02 nm/1 hPa in the X-direction and about 0.14 nm/1 hPa in the Y-direction. Thus, the measurement errors can be significantly decreased, and the measurement accuracy of the position of the stage can be improved.

The atmospheric pressure changes according to the passage of a high pressure area or a low pressure area (changes in the weather). The deformation amount of the drawing chamber 2a, or the deformation amount of the side wall 51a, changes due to the change of the atmospheric pressure. The force applied to the supporting portions 51b1 changes, while the deformation amount of the curved portion 51b2 also changes similarly. Therefore, the force applied to the supporting portions 51b1 due to the deformation of the curved portion 51b2 is advantageously offset by the force applied to the supporting portions 51b1 due to the deformation of the side wall 51a (caused by the above-described transmission of the force). As a result of this, the deformation of the supporting portions 51b1 can be suppressed. Since the supporting portions 51b1 are not deformed even when the atmospheric pressure changes, it is possible to suppress tilting of the stage moving mechanism 12 and the support body 55, that is, the two dimensional scale 13a and the encoder head 13b, due to the change of the atmospheric pressure. Accordingly, the generation of the measurement error in the stage position measuring unit 13 can be suppressed, and the deterioration of the measurement accuracy of the position of the stage can be suppressed.

The deformation of the curved portion 51b2 suppresses the deformation of the supporting portions 51b1, even when the curved portion 51b2 is made of a thin and low rigidity plate. Therefore, the above-described problem does not occur. There is no need to increase the thickness of the bottom plate 51b to prevent its deformation, and the bottom plate 51b can be formed as a thin plate. Therefore, reduction in the cost of materials and reduction of weight of the apparatus can be achieved. The thickness of the curved portion 51b2 can be made thinner than that of the supporting portions 51b1 to maintain the measurement accuracy of the position of the stage, while realizing the light-weight drawing chamber 2a.

The lid 53 and the supporting plate 55a2 are formed removably by attaching and detaching of the fixing members 54, 56, and removed by a maintenance worker during the maintenance work, such as replacement of the encoder head 13b (e.g., replacement due to failures or the expiry of service life), to allow maintenance of the encoder head 13b on the supporting plate 55a2. For example, the stage 11 and the stage moving mechanism 12 may interfere during the maintenance of the encoder head 13b when the maintenance is performed from above the drawing chamber 2a. By providing the lid 53 on the lower surface of the drawing chamber 2a and making the supporting plate 55a2 that supports the encoder head 13b be removable, the encoder head 13b and the supporting plate 55a2 can be removed together. Thus, the maintenance of the encoder head 13b can be performed easily, such that the maintenance ability (maintainability) can be improved. Similar procedures are executed for the maintenance of the position adjusting unit 57.

As described above, according to the embodiment, the supporting portions 51b1 that support the stage 11 and the stage moving mechanism 12, and the curved portion 51b2 having an externally curving projecting shape are provided on the bottom plate 51b. The force applied to the supporting portions 51b1 due to the deformation of the curved portion 51b2 is offset by the force applied to the supporting portions 51b1 due to the deformation of the side wall 51a. As a result, the deformation of the supporting portions 51b1 can be suppressed. The tilting of the installing surfaces formed as the upper surfaces of the supporting portions 51b1 can be suppressed, and the tilting of the stage moving mechanism 12 and the support body 55 due to the deformation of the drawing chamber 2a caused by the atmospheric pressure can be suppressed. Accordingly, the change of the positional relationship between the two dimensional scale 13a and the encoder head 13b due to the deformation of the drawing chamber 2a caused by the atmospheric pressure is suppressed, and the measurement error in the stage position measuring unit 13 can be suppressed. Therefore, the deterioration of the measurement accuracy of the position of the stage can be suppressed.

The beam structure has been adopted as the support body 55 including the end portions 55b1, such that each of the end portions 55b1 is attached to each of the supporting portion 51b1. A contact area between the support body 55 and each of the supporting portions 51b1 is decreased, and the oscillation of the support body 55 caused by the oscillation of the drawing chamber 2a can be suppressed. Thus, the generation of the measurement by the stage position measuring unit 13 due to the oscillation of the support body 55, i.e., the encoder head 13b, can be suppressed, and the deterioration of the measurement accuracy of measuring the position of the stage can be suppressed.

The encoder head 13b is provided on the supporting plate 55a2 of the support body 55 located above the lid 53, and the supporting plate 55a2 is formed removably from below. Therefore, the lid 53 is removed before the support body 55 and the encoder head 13b are removed, such that the maintenance of the encoder head 13b can be performed easily and the maintainability can be improved.

### Another Embodiment

In the embodiment described above, the two dimensional scale 13a is implemented by the scale with latticed graduations extending in the X- and Y-directions, but the two dimensional scale is not limited thereto. For example, a scale with latticed graduations in directions other than the X- and Y-directions may be used so long as the scale extends at least in two directions.

In the embodiment described above, the four joists 55b have been provided with adjacent joists 55b disposed at right angles, but the angle and the number of the joists are not limited thereto. The storing frame body 55a1, the joists 55b, and the ribs 55c have the longitudinal cross-sections in the short-length direction (i.e., are longer in the vertical direction), but the cross-sections are not limited thereto and other shape may be used. Further, the four ribs 55c have been provided, but the number of the ribs 55c is not limited to this, and a larger or a smaller number of ribs 55c may be provided so long as the oscillation can be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A charged particle beam drawing apparatus, comprising:
a vacuum container including a bottom plate, the bottom plate including a curved portion curved externally and a plurality of supporting portions disposed on an outer periphery of the curved portion;
a stage provided in the vacuum container and having a target object target object mounted on the stage;
a stage actuator supported by the supporting portions in the vacuum container and to move the stage;
a two dimensional scale provided on a lower surface of the stage;
a detector disposed under the two dimensional scale and detecting a position of the stage by the two dimensional scale; and
a support body including a plurality of end portions individually attached to the supporting portions, and to support the detector across the curved portion.

2. The charged particle beam drawing apparatus according to claim 1, wherein
the support body includes:
a plurality of joists; and
ribs to connect adjacent joists among the joists.

3. The charged particle beam drawing apparatus according to claim 2, wherein
each of end portions of the joists is attached to each of supporting portions, respectively.

4. The charged particle beam drawing apparatus according to claim 2, wherein
the joists have longitudinal cross-sections perpendicular to an extending direction of the joists.

5. The charged particle beam drawing apparatus according to claim 2, wherein
each of the supporting portions has a recessed portion, and
the end portions of the joists are fixed by individually fitting into the corresponding recessed portions.

6. The charged particle beam drawing apparatus according to claim 2, wherein
each of the joists has a through hole.

7. The charged particle beam drawing apparatus according to claim 1, further comprising:
a position adjuster provided on the support body and to adjust a position of the detector relative to the two dimensional scale.

8. The charged particle beam drawing apparatus according to claim 7, wherein
the position adjuster includes:
an angle adjuster to adjust an angle of the detector; and
a vertical driver to move the detector vertically.

9. The charged particle beam drawing apparatus according to claim 1, wherein
the support body includes a supporting plate that supports the detector and is removable from the side of the curved portion.

10. The charged particle beam drawing apparatus according to claim 9, further comprising:
a lid to removably close an opening formed in the curved portion, wherein
the supporting plate is disposed opposite to the lid.

11. The charged particle beam drawing apparatus according to claim 1, wherein
a force applied to the supporting portions due to deformation of the curved portion is offset by a force applied to the supporting portions due to deformation of a side wall of the vacuum container.
